(19) United States
(12) Patent Application Publication
(10) Pub. No.: US 2024/0149314 A1
(43) Pub. Date: May 9, 2024

(54) SUBSTRATE PROCESSING APPARATUS AND SUBSTRATE PROCESSING METHOD

(71) Applicant: Samsung Electronics Co., Ltd., Suwon-si (KR)

(72) Inventors: Hyunwoo Noh, Suwon-si (KR); Kyoungwoo Kim, Suwon-si (KR); Youngseok Jung, Suwon-si (KR); Youngjin Hong, Suwon-si (KR); Soochan Oh, Suwon-si (KR); Sungwoo Shin, Suwon-si (KR); Namhoon Lee, Suwon-si (KR); Bongju Lee, Suwon-si (KR)

(21) Appl. No.: 18/213,853

(22) Filed: Jun. 25, 2023

(30) Foreign Application Priority Data
Nov. 8, 2022 (KR) 10-2022-0148193

(51) Int. Cl. B08B 13/00; B08B 1/00; B08B 1/04; B08B 3/02

(52) U.S. Cl. CPC B08B 13/00; B08B 1/002; B08B 1/04; B08B 3/02

(57) ABSTRACT

Provided is a substrate processing apparatus configured to process a substrate having a notch including a plurality of rollers contacting a circumference of the substrate and configured to rotate the substrate, a first sensor configured to sense an impact between the plurality of rollers and the substrate, and a signal processing unit configured to detect revolutions per unit time of the substrate, based on a first sensing signal output by the first sensor.

### CROSS-REFERENCE TO RELATED APPLICATION

This application is based on and claims priority under 35 U.S.C. § 119 to Korean Patent Application No. 10-2022-0148193, filed on Nov. 8, 2022, in the Korean Intellectual Property Office, the disclosure of which is incorporated by reference herein in its entirety.

### BACKGROUND

The inventive concept relates to a substrate processing apparatus and a substrate processing method.

In manufacturing semiconductor devices, a polishing process, for example, chemical mechanical polishing (CMP) may be performed on a substrate, such as a wafer, and a cleaning process may be performed on the polished substrate. A cleaning process on a substrate may include, while rotating the substrate, supplying a cleaning solution on the substrate and physically cleaning the substrate by using a cleaning brush.

### SUMMARY

The inventive concept provides a substrate processing apparatus and a substrate processing method.

According to an aspect of the inventive concept, there is provided a substrate processing apparatus configured to process a substrate having a notch including a plurality of rollers contacting a circumference of the substrate and configured to rotate the substrate, a first sensor configured to sense impacts between the plurality of rollers and the substrate, and a signal processing unit configured to detect revolutions per unit time of the substrate, based on a first sensing signal output by the first sensor.

According to another aspect of the inventive concept, there is provided a substrate processing apparatus configured to process a substrate having a notch including a plurality of rollers arranged along a circumference of the substrate, and configured to rotate the substrate, a first support pillar configured to support a first roller which is one of the plurality of rollers, a first sensor bracket coupled to the first support pillar, a first sensor mounted on the first sensor bracket, and configured to sense vibrations generated by impacts between the plurality of rollers and the substrate, and a signal processing unit configured to detect a contact period between each of the plurality of rollers and the notch of the substrate based on a first sensing signal output by the first sensor.

According to another aspect of the inventive concept, there is provided a substrate processing apparatus configured to process a substrate having a notch including a plurality of rollers arranged along a circumference of the substrate, and configured to rotate the substrate, a first support pillar configured to support a first roller which is one of the plurality of rollers, a first sensor bracket coupled to the first support pillar, a first sensor mounted on the first sensor bracket, and configured to sense impacts between the plurality of rollers and the substrate, a signal processing unit configured to detect revolutions per unit time of the substrate based on a first sensing signal output by the first sensor, and configured to generate revolutions data of the revolutions per unit time of the substrate over time, a data transmission unit configured to transmit, to a server, the revolutions data transmitted by the signal processing unit, a cleaning brush configured to physically clean a main surface of the substrate, and rotate with respect to a direction in parallel with the main surface of the substrate, and a cleaning liquid spray nozzle configured to spray cleaning liquid to the substrate.

According to another aspect of the inventive concept, there is provided a substrate processing method including rotating a substrate by using a plurality of rollers contacting a circumference of the substrate, sensing impacts between the plurality of rollers and the substrate by using a first sensor, detecting revolutions per unit time of the substrate based on a first sensing signal output by the first sensor, and cleaning the substrate.

### BRIEF DESCRIPTION OF THE DRAWINGS

Embodiments will be more clearly understood from the following detailed description taken in conjunction with the accompanying drawings in which:

FIG. 1 is a schematic configuration diagram of a substrate processing apparatus, according to an example embodiment;

FIG. 2 is a schematic configuration diagram of a portion of a substrate processing apparatus, according to an example embodiment;

FIGS. 3 and 4 are schematic configuration diagrams of operation examples of the substrate processing apparatus of FIG. 1;

FIG. 5 is a flowchart of a method of detecting revolutions per unit time by using a substrate processing apparatus, according to an example embodiment;

FIG. 6 is a flowchart of an example of operation S130 in FIG. 5;

FIG. 7 is a schematic graph of a signal generated by processing a first sensing signal in a signal processing unit, according to an example embodiment;

FIG. 8 is a configuration diagram of a substrate processing apparatus, according to an example embodiment;

FIG. 9 is a configuration diagram of a portion of the substrate processing apparatus of FIG. 8; and

FIG. 10 is a flowchart of a substrate processing method, according to an example embodiment.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted.

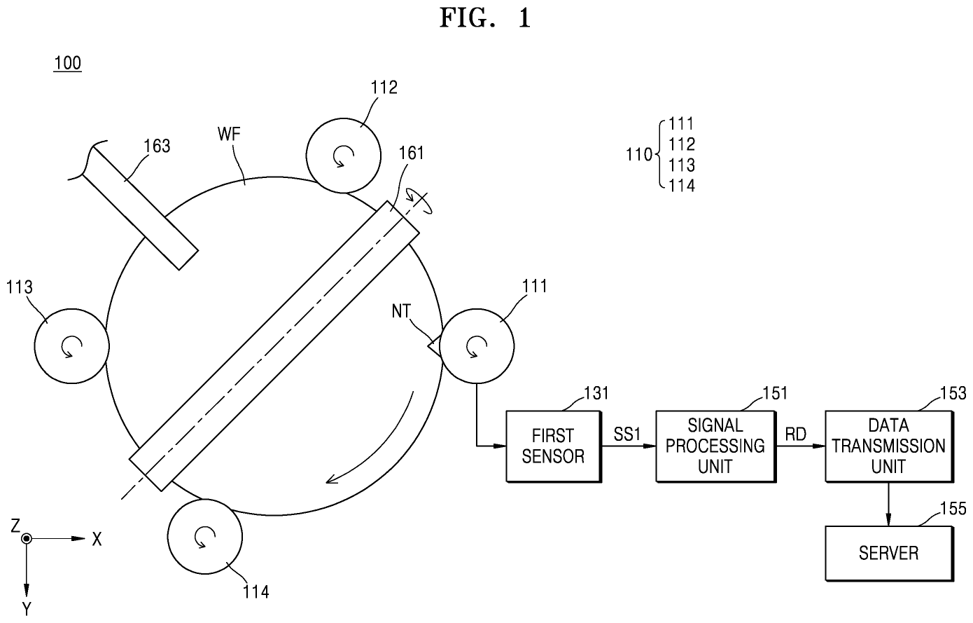

FIG. 1 is a schematic configuration diagram of a substrate processing apparatus 100, according to an example embodiment.

Referring to FIG. 1, the substrate processing apparatus 100 may be configured to perform a cleaning process on a substrate WF. For example, the substrate processing apparatus 100 may be configured to perform wet cleaning and/or dry cleaning on the substrate WF.

Here, the substrate WF may be referred to as the substrate WF itself or a stacked structure including the substrate WF and a material layer formed on the surface of the substrate WF. In addition, the term “surface of the substrate WF” may be referred to as a surface of the substrate WF itself or a surface of a material layer formed on the substrate WF. The substrate WF may have a circular shape in a plan view. The substrate WF may include, for example, a wafer. The substrate WF may have a notch NT around the substrate WF. The notch NT of the substrate WF may be understood as a groove formed around the substrate WF. The notch NT of the substrate WF may represent a crystal direction of the wafer, and may be used to align the substrate WF in a reference direction during a substrate treatment process. When the substrate WF includes a circular wafer with a constant diameter, the radius of the substrate WF (the distance between the center of the substrate WF and the circumference of the substrate WF) may be constant except for the portion where the notch NT is arranged.

The substrate processing apparatus 100 may include a plurality of rollers 110, a cleaning brush 161, and a cleaning liquid spray nozzle 163.

The plurality of rollers 110 may be arranged along the circumference of the substrate WF, and each of the plurality of rollers 110 may contact the circumference of the substrate WF. As illustrated in FIG. 1, the substrate processing apparatus 100 may include first to fourth rollers 111, 112, 113, and 114 arranged along the circumference of the substrate WF. For example, the first to fourth rollers 111, 112, 113, and 114 may be sequentially arranged along the circumference of the substrate WF. The plurality of rollers 110 may be spaced apart from each other at a certain interval along the circumference of the substrate WF, or may also be spaced apart from each other at different intervals. Although FIG. 1 illustrates that the substrate processing apparatus 100 includes four rollers 110, the substrate processing apparatus 100 may include two or more rollers 110.

The positions of the plurality of rollers 110 may be set based on the center of the substrate WF. For example, when a direction between the center of the first roller 111 and the center of the substrate WF is defined as a reference direction (or a reference axis), the position of each roller 110 may be defined by an angular position determined based on the reference direction. The first and third rollers 111 and 113 may be symmetrically arranged with respect to the center of the substrate WF, and the difference between the angular position of the first roller 111 and the angular position of the third roller 113 may be about 180 degrees. The angular position of the first roller 111 may be about 0 degrees, and the angular position of the third roller 113 may be about 180 degrees. The second and fourth rollers 112 and 114 may be symmetrically arranged with respect to the center of the substrate WF, and the difference between an angular position of the second roller 112 and an angular position of the fourth roller 114 may be about 180 degrees. The angular position of the second roller 112 may be less than about 90 degrees, and the angular position of the fourth roller 114 may be less than about 270 degrees. The angular position difference between the first roller 111 and the second roller 112 may be less than about 90 degrees, and the angular position difference between the third roller 113 and the fourth roller 114 may be less than about 90 degrees.

The plurality of rollers 110 may be configured to rotate the substrate WF. Each of the plurality of rollers 110 may rotate with respect to a vertical direction (for example, a Z direction) perpendicular to a main surface of the substrate WF (an upper surface or a lower surface of the substrate WF). The plurality of rollers 110 may rotate in contact with the circumference of the substrate WF, and the substrate WF may rotate in a vertical direction (that is, the Z direction) perpendicular to the main surface of the substrate WF by rotation of the plurality of rollers 110. A rotation axis of each roller 110 and a rotation axis of the substrate WF may be in parallel with the vertical direction (that is, the Z direction) perpendicular to the main surface of the substrate WF.

Each of the plurality of rollers 110 may move between a process position of contacting the substrate WF and a standby position of being spaced apart from the substrate WF. Each of the plurality of rollers 110 may be movably installed in a moving guide, and may be configured to be moved between the process position and the standby position by an actuator. The plurality of rollers 110 may be at the standby positions while the substrate WF is loaded on or unloaded from the substrate processing apparatus 100.

In some embodiments, a plurality of rollers 110 may include one or more driving rollers. A driving roller may be connected to an actuator, such as a motor, and may be configured to be rotated by the actuator. Rotation of the driving roller may rotate the substrate WF.

In some embodiments, some of the plurality of rollers 110 may include driving rollers, and the others may include idler rollers. An idler roller may not be connected to an actuator, and may be manually rotated by friction with the substrate WF rotated by the driving roller.

The cleaning liquid spray nozzle 163 may be configured to spray the cleaning liquid onto the substrate WF. The cleaning solution may contain water, deionized water, ethanol, isopropyl alcohol, or a mixture thereof. The substrate processing apparatus 100 may further include a cleaning liquid source for storing and supplying cleaning liquid, and a pipe for transferring the cleaning liquid between the cleaning liquid source and the cleaning liquid spray nozzle 163. The cleaning liquid spray nozzle 163 may be configured to spray the cleaning liquid onto the upper surface and/or the lower surface of the substrate WF. In some embodiments, the substrate processing apparatus 100 may include a plurality of cleaning liquid spray nozzles 163, and some of the plurality of cleaning liquid spray nozzles 163 may be configured to spray cleaning liquid onto the upper surface of the substrate WF, and others thereof may be configured to spray cleaning liquid onto the lower surface of the substrate WF.

The cleaning brush 161 may be configured to physically clean the substrate WF. In some embodiments, the substrate processing apparatus 100 may be configured to perform scrubber cleaning for cleaning the substrate WF while rotating the cleaning brush 161. The cleaning brush 161 may be configured to rotate with respect to a horizontal direction in parallel with the main surface of the substrate WF (that is, the upper surface or the lower surface of the substrate WF). Foreign materials and contaminants remaining on a surface of the substrate WF may be removed by friction between the cleaning brush 161 and the substrate WF during the rotation of the cleaning brush 161. In some embodiments, the substrate processing apparatus 100 may include one cleaning brush 161. In some embodiments, the substrate processing apparatus 100 may include two cleaning brushes 161 spaced apart from each other with the substrate WF therebetween, such that one of the two cleaning brushes 161 may be configured to clean the upper surface of the substrate WF, and the other may be configured to clean the lower surface of the substrate WF.

The substrate processing apparatus 100 may be configured to detect revolutions per unit time of the substrate WF while the substrate WF is rotated by the plurality of rollers 110. For example, the substrate processing apparatus 100 may be configured to detect revolutions per minute (rpm) of the substrate WF.

The substrate processing apparatus 100 may include a first sensor 131 connected to at least one of the plurality of rollers 110, a signal processing unit 151 configured to detect revolutions per unit time of the substrate WF based on a first sensing signal SS1 output by the first sensor 131, and a data transmission unit 153 configured to receive revolutions data RD of revolutions per unit time of the substrate WF generated by the signal processing unit 151 and transmit the revolutions data RD to another device of the substrate processing apparatus 100. For example, the data transmission unit 153 may transmit the revolutions data RD to a server 155.

The first sensor 131 may be connected to the first roller 111, which is one of the plurality of rollers 110, and may be configured to detect in real time an impact between the rollers 110 and the substrate WF and/or vibration generated by the impact, while the substrate WF is rotated by the plurality of rollers 110.

While the substrate WF rotates, relatively big impact and/or vibrations may be detected by the first sensor 131 at a time point when the rollers 110 contact the notch NT of the substrate WF, and relatively small impact and vibrations may be detected by the first sensor 131 at a time point when the rollers 110 contact other portions of the circumference of the substrate WF except for the notch NT of the substrate WF. When the rollers 110 contact the notch NT of the substrate WF, the amplitude of the first sensing signal SS1 may be proportional to the magnitude of the impact between the rollers 110 and the substrate WF and/or the magnitude of the vibration generated by the impact. Because relatively large impact and/or vibrations occur when the rollers 110 contact the notch NT of the substrate WF, the first sensor 131 may detect an impact between the first roller 111 and the substrate WF as well as an impact between the second through fourth rollers 112, 113, and 114 and the substrate WF. Accordingly, during one rotation of the substrate WF, the number of peak points of the first sensing signal SS1 output by the first sensor 131 may correspond to the number of rollers 110. For example, when the substrate processing apparatus 100 includes four rollers 110, the first sensing signal SS1 output by the first sensor 131 may have four peak points during one rotation of the substrate WF.

In some embodiments, the first roller 111, to which the first sensor 131 is connected, may include a driving roller. In some embodiments, the first roller 111, to which the first sensor 131 is connected, may include an idler roller.

The first sensor 131 may include various sensors for measuring an impact between the plurality of rollers 110 and the substrate WF and/or vibration generated by the impact. In some embodiments, the first sensor 131 may include a contact-type sensor. In some embodiments, the first sensor 131 may include a non-contact-type sensor. In embodiments, the first sensor 131 may include at least one of a vibration sensor, an acceleration sensor, a decompression sensor, a displacement sensor, a load sensor, a strain gauge, a piezo sensor, an infrared sensor, a hall sensor, and a load cell.

In FIG. 1, the substrate processing apparatus 100 is illustrated as including the first sensor 131 connected to the first roller 111, but in some embodiments, the substrate processing apparatus 100 may also include a plurality of sensors connected to different rollers 110. In this case, each of the plurality of sensors may be configured to detect an impact between the plurality of rollers 110 and the substrate WF and/or vibration generated by the impact. The number of sensors may be equal to the number of rollers 110, or may be less than the number of rollers 110.

The signal processing unit 151 may receive the first sensing signal SS1 output by the first sensor 131, and process the first sensing signal SS1 to detect the revolutions per unit time of the substrate WF. The signal processing unit 151 may be connected to the first sensor 131 to transmit a signal, and may include a serial communication module and an analog to digital conversion (ADC) module. One of the serial communication module and the ADC module may be selected and driven according to the type of the first sensor 131. The signal processing unit 151 may generate revolutions data RD of the number of revolutions per unit time of the substrate WF over time, and transmit in real time the revolutions data RD to the data transmission unit 153. For example, when the unit time is minutes, the revolutions data RD may include information about the rpm change of the substrate WF over time.

The signal processing unit 151 may detect a peak point generation period of the first sensing signal SS1, and may detect the revolutions per unit time of the substrate WF based on the peak point generation period of the first sensing signal SS1. In some embodiments, the signal processing unit 151 may process the first sensing signal SS1 and detect a contact time point and/or a contact period between each of the plurality of rollers 110 and the notch NT of the substrate WF, and may detect the revolutions per unit time of the substrate WF from the contact time point and/or the contact period between the plurality of rollers 110 and the notch NT. For example, because the arrangement of the plurality of rollers 110 (that is, the positions of the plurality of rollers 110) is known, a contact period between a particular roller and the notch NT of the substrate WF may be detected from information about the arrangement of the plurality of rollers 110 and information about peak points of the first sensing signal SS1, and the revolutions per unit time of the substrate WF may be detected from the contact period between a particular roller and the notch NT of the substrate WF.

In embodiments, the signal processing unit 151 may detect the position of the notch NT of the substrate WF while the substrate WF rotates based on information about the arrangement of the plurality of rollers 110 and information about the contact period between the plurality of rollers 110 and the notch NT of the substrate WF, and may detect the position of the notch NT of the substrate WF immediately after the rotation of the substrate WF is completed due to the plurality of rollers 110.

The signal processing unit 151 may include at least one processor configured to process the first sensing signal SS1, and a memory device configured to store various data. In some embodiments, the signal processing unit 151 may include a plurality of processors configured to process the first sensing signal SS1. The processor may be configured to perform certain operations and algorithms, and may include, for example, a microprocessor, a central processing unit (CPU), a graphics processing unit (GPU), etc. The memory device may include read only memory (ROM), random access memory (RAM), etc. In some embodiments, the signal processing unit 151 may include a monitoring display device for field monitoring.

The data transmission unit 153 may receive the revolutions data RD from the signal processing unit 151, and may transmit the revolutions data RD to a server 155. The data transmission unit 153 may include a communication module for communication with other devices, for example, an Internet of Things (IoT) module, a Wi-Fi module, a Bluetooth module, etc. In some embodiments, when the revolutions data RD is outside a preset allowable range, the data transmission unit 153 may generate an alarm or generate an interlock signal for controlling the operation of the substrate processing apparatus 100. For example, when the revolutions data RD indicates that the revolutions per unit time are greater than a maximum amount of the preset allowable range or less than a minimum amount of the preset allowable range, the data transmission unit 153 may generate an alarm or generate an interlock signal for controlling the operation of the substrate processing apparatus 100.

The substrate processing apparatus 100 may include a controller configured to control the entire process by using the substrate processing apparatus 100. The controller may be configured to receive the revolutions data RD from the data transmission unit 153, and control the entire process of the substrate processing apparatus 100 based on the revolutions data RD. In some embodiments, when the revolutions data RD detected in real time is outside the preset allowable range, the controller may stop the operation of the plurality of rollers 110, the operation of the cleaning brush 161, and/or the operation of the cleaning liquid spray nozzle 163.

The controller may be implemented as hardware, firmware, software, or a combination thereof. For example, the controller may include a computing device, such as a workstation computer, a desktop computer, a laptop computer, a tablet computer, etc. For example, the controller may include a memory device, such as ROM and RAM, and a processor configured to perform a certain operation and algorithm. The processor may include, for example, a microprocessor, a CPU, a GPU, etc.

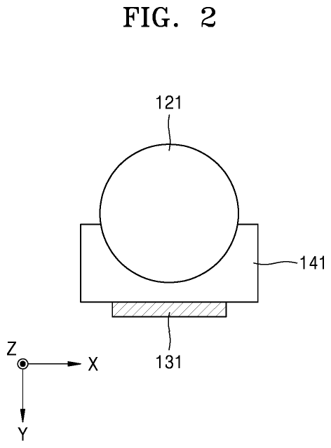

FIG. 2 is a schematic configuration diagram of a portion of the substrate processing apparatus 100, according to an example embodiment.

Referring to FIGS. 1 and 2, the substrate processing apparatus 100 may include a plurality of support pillars supporting the plurality of rollers 110. In FIG. 2, a first support pillar 121 configured to support the first roller 111 is illustrated as an example, and support pillars configured to support the second through fourth rollers 112, 113, and 114 may be substantially the same as the first support pillar 121. Each of the plurality of support pillars may have a circular pillar shape. Each support pillar may support one corresponding roller 110. For example, each roller 110 may rotate on a corresponding individual support pillar, and the corresponding individual support pillar may be fixed while each roller 110 rotates. For example, a rotating shaft of each roller 110 may be inserted into a corresponding support pillar, and the vibration of each roller 110 may be transmitted to the corresponding support pillar via the rotating shaft.

The substrate processing apparatus 100 may include a first sensor bracket 141 on which the first sensor 131 is mounted. The first sensor 131 may be fixed to one side of the first sensor bracket 141, and the first sensor bracket 141 may be coupled or attached to the first support pillar 121. For example, the first sensor bracket 141 may be coupled to a side surface of the first support pillar 121, and a side surface of the first sensor bracket 141 facing the first support pillar 121 may have a concave shape corresponding to the side surface of the first support pillar 121. In example embodiments, the first sensor bracket 141 may be coupled to the first support pillar 121 using a bracket or an adhesive. Impact and/or vibration generated by a contact between the plurality of rollers 110 and the substrate WF while the substrate WF rotates may be transmitted to the first sensor 131 via the first support pillar 121 and the first sensor bracket 141.

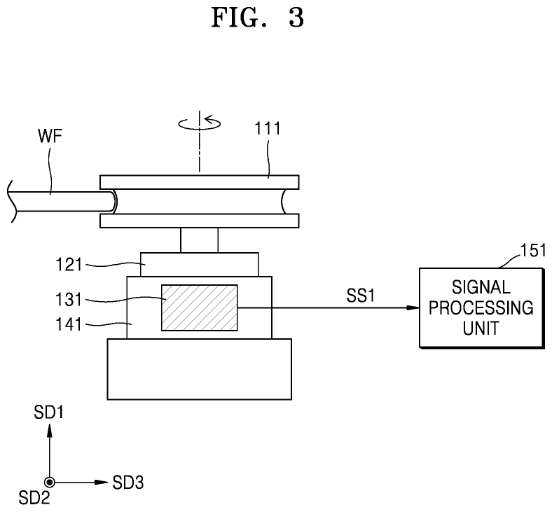

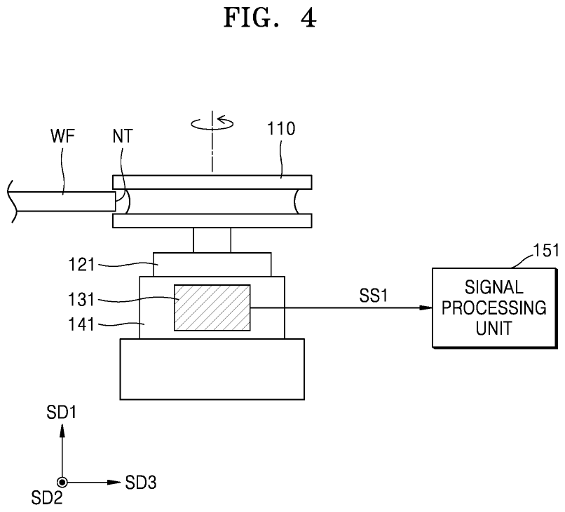

FIGS. 3 and 4 are schematic configuration diagrams of operation examples of the substrate processing apparatus 100 of FIG. 1. FIG. 3 illustrates a state in which the first roller 111 contacts the circumference of the substrate WF, and FIG. 4 illustrates a state in which the first roller 111 contacts a circumferential portion of the substrate WF with the notch NT provided therein.

Referring to FIGS. 1 through 4, the first sensor 131 may be connected to a side surface of the first support pillar 121 via the first sensor bracket 141, and may be configured to sense vibration transmitted via the first support pillar 121 and the first sensor bracket 141.

The first sensor 131 may be configured to detect an impact between the plurality of rollers 110 and the substrate WF and/or vibration generated due to the impact in three sensing directions perpendicular to each other (that is, a first sensing direction SD1, a second sensing direction SD2, and a third sensing direction SD3). The first sensing direction SD1 may be an axial direction of the first support pillar 121 (for example, the direction perpendicular to the upper surface of the substrate WF or the Z direction), the second sensing direction SD2 may be a direction perpendicular to a sensing surface of the first sensor 131 (for example, a tangent direction of the substrate WF at a contact point between the first roller 111 and the substrate WF), and the third sensing direction SD3 may be a tangent direction of a side surface of the first support pillar 121 (for example, a radial direction of the substrate WF at the contact point between the first roller 111 and the substrate WF). Accordingly, the first sensing signal SS1 may include first sub sensing data of an impact and/or vibration measured in the first sensing direction SD1, second sub sensing data of an impact and/or vibration measured in the second sensing direction SD2, and third sub sensing data of an impact and/or vibration measured in the third sensing direction SD3. For example, when the first sensor 131 is an acceleration sensor, the first sensor 131 may sense an acceleration of the first roller 111 over time in the first through third sensing directions SD1, SD2, and SD3, and the first sensing signal SS1 output by the first sensor 131 may include data of the acceleration of the first roller 111 measured in the first through third sensing directions SD1, SD2, and SD3.

The signal processing unit 151 may detect the revolutions per unit time of the substrate WF based on at least one of the first through third sub sensing data. In some embodiments, the signal processing unit 151 may detect the revolutions per unit time of the substrate WF based on all of the first through third sub sensing data. For example, when the first sensor 131 includes an acceleration sensor, the signal processing unit 151 may detect the revolutions per unit time of the substrate WF based on data obtained by adding all the first through third sub sensing data. In some embodiments, the signal processing unit 151 may detect the revolutions per unit time of the substrate WF based on two pieces of sub sensing data among the first through third sub sensing data. For example, when the first sensor 131 includes an acceleration sensor, the signal processing unit 151 may detect the revolutions per unit time of the substrate WF based on data obtained by summing the first sub sensing data and the second sub sensing data. In some embodiments, the signal processing unit 151 may detect the revolutions per unit time of the substrate WF based on any one piece of sub sensing data among the first through third sub sensing data. In some embodiments, the signal processing unit 151 may be configured to detect the revolutions per unit time of the substrate WF based on the first sub sensing data and the second sub sensing data except for the third sub sensing data among the first through third sub sensing data.

In some embodiments, the signal processing unit 151 may determine one or more interested rollers (e.g., rollers of interest) among the plurality of rollers 110, and amplify a component of the first sensing signal SS1 by using an impact between one or more interested rollers and the notch NT of the substrate WF. For example, in the first sensing signal SS1, a relatively large weight may be multiplied to a peak point related to an impact between one or more interested rollers and the notch NT of the substrate WF, and a relatively small weight may be multiplied to a peak point related to an impact between other rollers and the notch NT of the substrate WF.

When the first sensor 131 detects the impact between the plurality of rollers 110 and the notch NT of the substrate WF in the first sensing direction SD1, the signals due to the impact between each of the first through fourth rollers 111, 112, 113, and 114 and the notch NT of the substrate WF may be relatively similar to each other. On the other hand, when the first sensor 131 detects the impact between the plurality of rollers 110 and the notch NT of the substrate WF in the second sensing direction SD2, because the first roller 111 and the third roller 113 are arranged at an angular position of about 180 degrees, the magnitude of the signal due to the impact between each of the first roller 111 and the third roller 113 and the notch NT of the substrate WF may be relatively large, and the magnitude of the signal due to the impact between each of the second roller 112 and the fourth roller 114 and the notch NT of the substrate WF may be relatively small. When the signal processing unit 151 detects the revolutions per unit time of the substrate WF based on the data generated by adding the first and second sub sensing data, by determining the first roller 111 and the third roller 113 as the interested rollers and amplifying components related to the impact between the first roller 111 and the third roller 113 and the notch NT of the substrate WF, the signal processing unit 151 may improve detection reliability of the revolutions per unit time of the substrate WF.

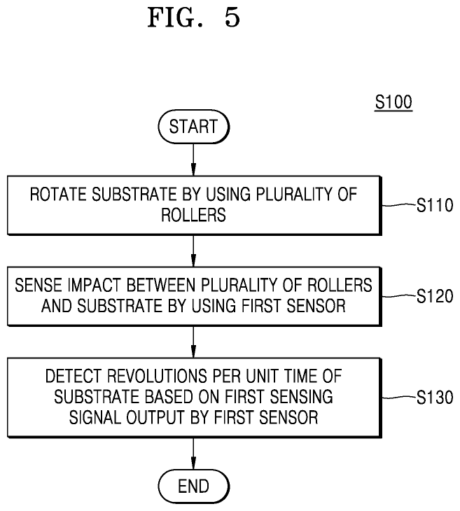

FIG. 5 is a flowchart of a method S100 of detecting the revolutions per unit time of the substrate WF by using the substrate processing apparatus 100, according to an example embodiment. Hereinafter, the method S100 of detecting the revolutions per unit time of the substrate WF according to embodiments is described with reference to FIG. 5 together with FIGS. 1 through 4.

Firstly, the substrate WF may be rotated by using the plurality of rollers 110 (S110). For example, in a plan view, as the plurality of rollers 110 rotate in a first rotation direction (for example, a counterclockwise direction), the substrate WF may rotate in a second rotation direction opposite to the first rotation direction (for example, a clockwise direction).

Next, while the substrate WF is rotated by the plurality of rollers 110, the impact between the plurality of rollers 110 and the substrate WF and/or the vibration generated by the impact may be detected by the first sensor 131 (S120). The first sensor 131 may detect an impact generated between each of the plurality of rollers 110 and the substrate WF and/or vibration generated by the impact while the substrate WF rotates.

Next, based on the first sensing signal SS1 output by the first sensor 131, the revolutions per unit time of the substrate WF may be detected (S130). The signal processing unit 151 may generate the revolutions per unit time of the substrate WF based on the first sensing signal SS1, and may generate the revolutions data RD. The signal processing unit 151 may detect, from the first sensing signal SS1, the contact period between a particular roller (for example, the first roller 111) and the notch NT of the substrate WF, and may detect a change of revolutions of the substrate WF from the contact period between the particular roller and the notch NT of the substrate WF over time. For example, when the contact period between the particular roller and the notch NT of the substrate WF is about 1 second, the rpm of the substrate WF may be about 60.

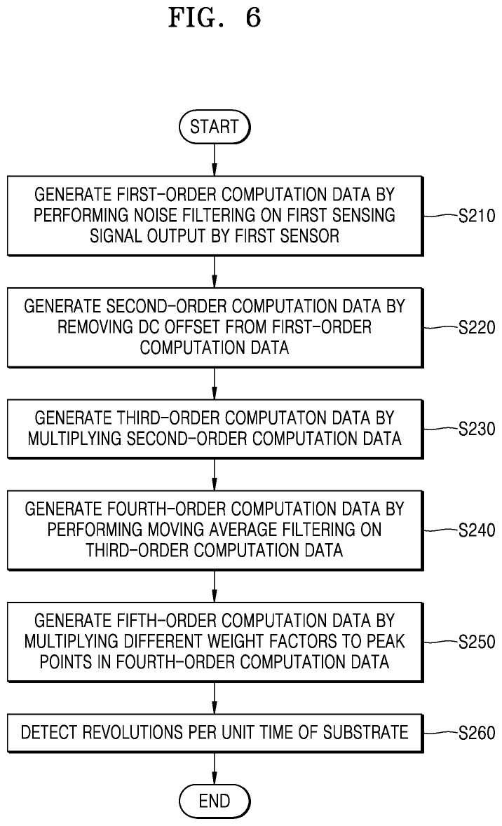

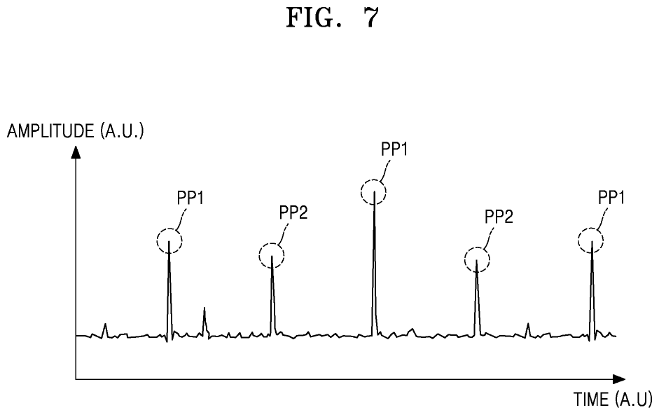

FIG. 6 is a flowchart of an example of operation S130 in FIG. 5. FIG. 7 is a schematic graph of a signal generated by processing the first sensing signal SS1 in the signal processing unit 151. Hereinafter, a method of detecting the revolutions per unit time of the substrate WF according to example embodiments is described with reference to FIGS. 6 and 7 together with FIGS. 1 through 4.

Firstly, the signal processing unit 151 may receive the first sensing signal SS1 output by the first sensor 131, and generate first-order computation data by performing a noise filtering on the first sensing signal SS1 (S210). In some embodiments, the noise filtering may include a low pass filter. For example, a cutoff frequency of the noise filtering may be determined as between about 20 Hz and about 30 Hz. However, the noise filtering is not limited to the low pass filter, and the noise filtering may include a low pass filter, a moving average filter, and/or a filter using a mean squared error.

Next, second-order computation data may be generated by removing a direct current (DC) offset from the first-order computation data (S220). For example, generating the second-order computation data may include obtaining a cumulative average from the first-order computation data and subtracting the cumulative average from the first-order computation data to remove the DC offset from the first-order computation data.

Next, third-order computation data, in which the second-order computation data has been squared to remove a negative component, may be generated (S230). For example, when the first sensor 131 includes an acceleration sensor, because the first sensing signal SS1 includes a positive value and a negative value, the negative value may be removed by squaring the second-order computation data.

Next, fourth-order computation data may be generated by performing a moving average filtering on the third-order computation data (S240).

Next, fifth-order computation data may be generated by multiplying different weight factors to the peak points of the fourth-order computation data (S250). Operation S250 may be performed to amplify values related with an impact between one or more interested rollers among the plurality of rollers 110 and the notch NT of the substrate WF. In operation S250, the one or more interested rollers may be determined, and the peak point generation periods of the interested peak points (e.g., peak points of interest) related with the one or more interested rollers may be determined by using information about the arrangement of the plurality of rollers 110 (that is, angular positions of the plurality of rollers 110). When the peak point generation periods of the interested peak points are determined (referred to herein as “interested peak point generation periods”), in the fourth-order computation data, relatively large weight factors may be multiplied to the peak points in the peak point generation period of the interested peak points, and relatively small weight factors may be multiplied to other peak points.

In some embodiments, the first roller 111 and the third roller 113, which have an angular position difference of about 180 degrees, may be determined as interested rollers, and in the fourth-order computation data, the time between the peak point caused by the impact between the first roller 111 and the notch NT of the substrate WF and the peak point caused by the third roller 113 and the notch NT of the substrate WF may be determined as the interested peak point generation period. In the fourth-order computation data, relatively large weight factors may be multiplied to the peak points in the interested peak point generation period, and relatively small weight factors may be multiplied to other peak points. As a result, as illustrated in FIG. 7, peak points PP1 caused by the impact between the first roller 111 and the notch NT of the substrate WF and peak points PP2 caused by the impact between the third roller 113 and the notch NT of the substrate WF may be amplified.

In some embodiments, the signal processing unit 151 may generate the fourth-order computation data by sequentially performing operation S210, operation S220, operation S230, and operation S240 based on the first and second sub sensing data except the third sub sensing data among the first through third sub sensing data transmitted by the first sensor 131, and in processing the fourth-order computation data, may multiply a relatively large weight factor to values related with the first roller 111 and the third roller 113, which have been determined as the interested rollers and may multiply a relatively small weight factor to values related with the second roller 112 and the fourth roller 114.

Next, the signal processing unit 151 may detect revolutions per unit time of the substrate WF based on the fifth-order computation data (S260). For example, when the generation period of the peak points PP1 related with the impact between the first roller 111 and the notch NT of the substrate WF is about 1 second, the rpm of the substrate WF may be about 60. In some embodiments, operations S210 through S260 may be performed by different processors of the signal processing unit 151.

A substrate processing apparatus according to a comparison example may detect revolutions per unit time of a substrate by recognizing a magnet attached to an idler roller as a hall sensor provided outside the idler roller. In the case of the substrate processing apparatus, when a friction force between the idler roller and the substrate is reduced due to an inflow of a cleaning liquid used for treating the substrate, there may be an issue that a slip between the idler roller and the substrate occurs, and the revolutions per unit time of the substrate detected due to the slip between the idler roller and the substrate is less than the actual revolutions per unit time of the substrate. When the detected revolutions per unit time of the substrate is less than the actual revolutions per unit time of the substrate, a false interlock signal may be generated, and an operation rate of the facility may be reduced.

However, according to embodiments of the inventive concept, because an impact between the plurality of rollers 110 and the substrate WF and/or vibration generated by the impact are detected by using a sensor and the revolutions per unit time of the substrate WF is detected based on a sensing signal output by the sensor, even when a slip occurs between the plurality of rollers 110 and the substrate WF, the revolutions per unit time of the substrate WF may be detected with high reliability. As the reliability of detecting the revolutions per unit time of the substrate WF is improved, an issue of the reduction in the operation rate of a facility may be prevented by using the false interlock signal.

Furthermore, according to embodiments of the inventive concept, because it is possible to improve a signal-to-noise ratio (SNR) by noise removal on a sensing signal output by a sensor, treatment for amplifying a necessary peak component, or the like, the detection reliability of the revolutions per unit time of the substrate WF may be further improved.

Furthermore, according to embodiments of the inventive concept, a sensing signal output by a sensor may be utilized as an inspection reference. Because a contact time point between the plurality of rollers 110 and the notch NT of the substrate WF may be detected, when a value of a signal generated by a contact between a particular roller and the notch NT of the substrate WF changes greatly according to a detection time point, a defect may be determined to have occurred in the particular roller and inspection on the particular roller may be performed.

Furthermore, according to embodiments of the inventive concept, the first sensing signal SS1 and/or the revolutions data RD, which are detected, may be utilized as a facility inspection reference. For example, when the substrate treatment process is performed by using the substrate processing apparatus 100, and the first sensing signal SS1 and/or the revolutions data RD, which have been detected, are outside of a preset allowable range, a facility inspection for removing defective factors may be performed. In addition, when the substrate treatment process is performed on a plurality of substrate processing apparatuses 100, by comparing the first sensing signal SS1 and/or the revolutions data RD detected in each of plurality of substrate processing apparatuses 100, whether there is a problem in a facility setting status in each of the plurality of substrate processing apparatuses 100 may be identified.

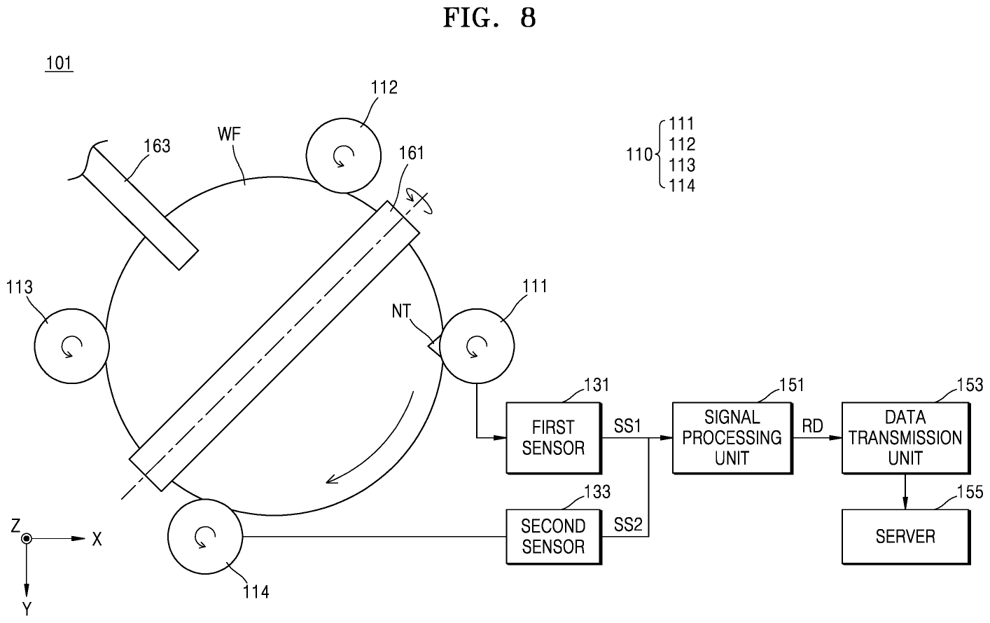

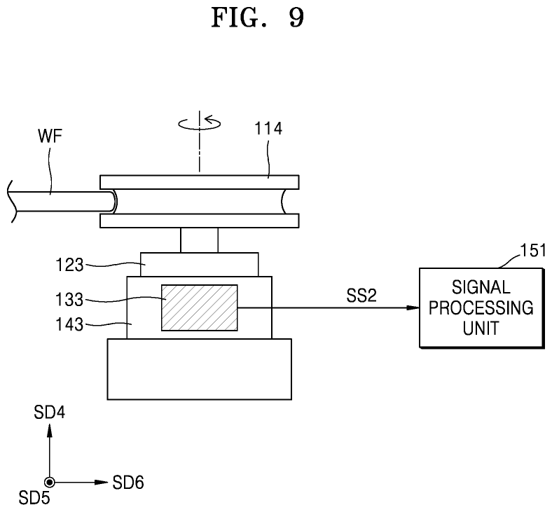

FIG. 8 is a configuration diagram of a substrate processing apparatus 101 according to an example embodiment. FIG. 9 is a configuration diagram of a portion of the substrate processing apparatus 101 of FIG. 8. Hereinafter, the substrate processing apparatus 101 of FIGS. 8 and 9 is described mainly with respect to the differences from the substrate processing apparatus 100 described with reference to FIGS. 1 through 4.

Referring to FIG. 8, the substrate processing apparatus 101 may include a plurality of sensors connected to two or more rollers 110 among the plurality of rollers 110. In some embodiments, the substrate processing apparatus 101 may further include a second sensor 133 connected to the fourth roller 114, in addition to the first sensor 131 connected to the first roller 111.

The second sensor 133 may include a sensor of the same type as the first sensor 131. Similar to the descriptions given above for the first sensor 131, the second sensor 133 may be mounted on a second sensor bracket 143, and the second sensor bracket 143 may be coupled or attached to a side surface of a second support pillar 123. The first roller 111 and the fourth roller 114 each may include a driving roller, or may also include an idler roller. The second sensor 133 may be configured to detect an impact between the plurality of rollers 110 and the substrate WF and/or vibration generated by the impact, and may output a second sensing signal SS2. A sensing method of the second sensor 133 may be substantially the same as a sensing method of the first sensor 131 described above, and thus, duplicate descriptions thereof are omitted.

The second sensor 133 may be configured to detect an impact between the plurality of rollers 110 and the substrate WF and/or vibration generated due to the impact in three sensing directions perpendicular to each other (that is, a fourth sensing direction SD4, a fifth sensing direction SD5, and a sixth sensing direction SD6). The fourth sensing direction SD4 may be an axial direction of the second support pillar 123 (for example, the direction perpendicular to the upper surface of the substrate WF or the Z direction), the fifth sensing direction SD5 may be a direction perpendicular to a sensing surface of the second sensor 133 (for example, a tangent direction of the substrate WF at a contact point between the fourth roller 114 and the substrate WF), and the sixth sensing direction SD6 may be a tangent direction of a side surface of the second support pillar 123 (for example, a radial direction of the substrate WF at the contact point between the fourth roller 114 and the substrate WF). Accordingly, the second sensing signal SS2 may include fourth sub sensing data of an impact and/or vibration measured in the fourth sensing direction SD4, the fifth sub sensing data of an impact and/or vibration measured in the fifth sensing direction SD5, and the sixth sub sensing data of an impact and/or vibration measured in the sixth sensing direction SD6. For example, when the second sensor 133 includes an acceleration sensor, the second sensor 133 may sense an acceleration of the fourth roller 114 over time in the fourth through sixth sensing directions SD4, SD5, and SD6, and the second sensing signal SS2 output by the second sensor 133 may include data of the acceleration of the fourth roller 114 measured in the fourth through sixth sensing directions SD4, SD5, and SD6. In some embodiments, the signal processing unit 151 may detect the revolutions per unit time of the substrate WF based on at least one of the fourth through sixth sub sensing data. In some embodiments, the signal processing unit 151 may detect the revolutions per unit time of the substrate WF, based on at least one of the first through third sub sensing data of the first sensing signal SS1 of the first sensor 131 and at least one of the fourth through sixth sub sensing data of the second sensing signal SS2 of the second sensor 133. For example, the signal processing unit 151 may detect the revolutions per unit time of the substrate WF, based on at least one of the first through third sub sensing data of the first sensing signal SS1 of the first sensor 131 and at least one of the fourth through sixth sub sensing data of the second sensing signal SS2 of the second sensor 133 according to the operations described above in connection with FIGS. 5 and 6.

The signal processing unit 151 may be configured to detect the revolutions per unit time of the substrate WF based on the first sensing signal SS1 output by the first sensor 131 and the second sensing signal SS2 output by the second sensor 133. Because the revolutions per unit time of the substrate WF is detected by using a combination of sensing signals output by the first sensor 131 and the second sensor 133, a signal generated by a contact between each of the plurality of rollers 110 and the notch NT of the substrate WF may be amplified, and the SNR may be increased. In addition, by combining sensing signals output by the first sensor 131 and the second sensor 133, the contact timing point and a contact period between each of the plurality of rollers 110 and the substrate WF may be accurately detected. Furthermore, because the first sensor 131 and the second sensor 133 are included, a normal operation of the facility may be possible even when either the first sensor 131 or the second sensor 133 is defective, and thus, the operation rate of the facility may be increased.

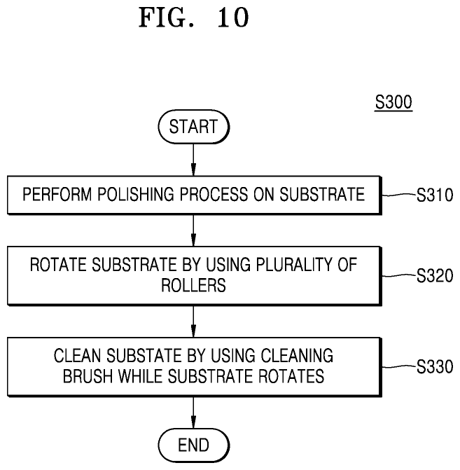

FIG. 10 is a flowchart of a substrate processing method S300 according to an embodiment. Hereinafter, the substrate processing method S300 according to embodiments of the inventive concept is described with reference to FIGS. 1 and 10.

Firstly, the substrate WF including at least one material layer, and a polishing process may be performed on the substrate WF (S310). For example, the polishing process on the substrate WF may include chemical mechanical polishing, grinding, etc.

Next, the substrate WF may be arranged so that the plurality of rollers 110 of the substrate processing apparatus 100 contact the circumference of the substrate WF, and then, the substrate WF may be rotated by using the plurality of rollers 110 (S320). For example, after the substrate WF is arranged at a preset process position, the plurality of rollers 110 may be moved from the standby position to the process position so that the plurality of rollers 110 contact the circumference of the substrate WF. As at least one of the plurality of rollers 110 rotates, the substrate WF may rotate.

Next, while the substrate WF rotates, the substrate WF may be cleaned by using the cleaning brush 161 (S330). For example, the cleaning brush 161 rotates with respect to a horizontal direction in parallel with the main surface of the substrate WF (that is, the upper surface or the lower surface of the substrate WF), and thus, due to friction between the rotating cleaning brush 161 and the rotating substrate WF, contaminants on the substrate WF may be removed. While the substrate WF is cleaned by using the cleaning brush 161, the cleaning liquid spray nozzle 163 may spray the cleaning liquid to the substrate WF.

Further processes may be performed on the substrate WF, for example to form a semiconductor device. For example, additional conductive and insulating layers may be deposited on the substrate WF to form semiconductor chips, the semiconductor chips may then be singulated, packaged on a package substrate, and encapsulated by an encapsulant to form a semiconductor package.

According to embodiments of the inventive concept, the substrate processing apparatus 100 may detect the revolutions per unit time of the substrate WF while the substrate WF is cleaned, and the operation of the substrate processing apparatus 100 may be controlled based on the detected revolutions per unit time of the substrate WF. When the number of revolutions per unit time of the substrate WF is outside the preset allowable range, an alarm or interlock signal may be generated to control the operation of the substrate processing apparatus 100. According to embodiments of the inventive concept, because the number of revolutions per unit time of the substrate WF is precisely detected, it may be possible to prevent an issue of the operation rate of the facility from being reduced due to a false alarm or a caustic interlock signal.

While the inventive concept has been particularly shown and described with reference to embodiments thereof, it will be understood that various changes in form and details may be made therein without departing from the spirit and scope of the following claims.

1. A substrate processing apparatus configured to process a substrate having a notch, the substrate processing apparatus comprising:
a plurality of rollers contacting a circumference of the substrate and configured to rotate the substrate;
a first sensor configured to sense impacts between the plurality of rollers and the substrate; and
a signal processing unit configured to detect revolutions per unit time of the substrate, based on a first sensing signal output by the first sensor.

2. The substrate processing apparatus of claim 1, wherein the first sensor comprises at least one of a vibration sensor, an acceleration sensor, and a decompression sensor.

3. The substrate processing apparatus of claim 1, wherein the signal processing unit is configured to detect the revolutions per unit time of the substrate based on a peak point generation period of the first sensing signal.

4. The substrate processing apparatus of claim 1, wherein the signal processing unit is configured to detect a contact period between each of the plurality of rollers and the notch of the substrate.

5. The substrate processing apparatus of claim 1, further comprising:
a first support pillar supporting a first roller which is one of the plurality of rollers,
wherein the first sensor is connected to the first support pillar.

6. The substrate processing apparatus of claim 5, further comprising:
a sensor bracket on which the first sensor is mounted,
wherein the sensor bracket is coupled to the first support pillar.

7. The substrate processing apparatus of claim 5, further comprising:
a second support pillar supporting a second roller which is one of the plurality of rollers; and
a second sensor connected to the second support pillar, and configured to sense the impacts between the plurality of rollers and the substrate,
wherein the signal processing unit is configured to detect the revolutions per unit time of the substrate based on the first sensing signal and a second sensing signal output by the second sensor.

8. The substrate processing apparatus of claim 5,
wherein the first sensor is configured to sense the impacts between the plurality of rollers and the substrate in a first sensing direction, a second sensing direction, and a third sensing direction, which are perpendicular to each other,
wherein the impacts include an impact between the plurality of rollers and the substrate, an impact between the plurality of rollers and the substrate, and an impact between the plurality of rollers and the substrate,
wherein the first sensing signal comprises first sub sensing data of the impact between the plurality of rollers and the substrate, sensed in the first sensing direction, second sub sensing data of the impact between the plurality of rollers and the substrate, sensed in the second sensing direction, and third sub sensing data of the impact between the plurality of rollers and the substrate, sensed in the third sensing direction, and
wherein the signal processing unit is configured to detect the revolutions per unit time of the substrate based on at least one of the first through third sub sensing data.

9. The substrate processing apparatus of claim 8,
wherein the first sensing direction is a direction vertical to a main surface of the substrate, and the second sensing direction is a tangent direction of the substrate at a contact point between the first roller and the substrate, and
wherein the signal processing unit is configured to detect the revolutions per unit time of the substrate based on the first sub sensing data and the second sub sensing data.

10. The substrate processing apparatus of claim 5, wherein the first roller comprises a driving roller configured to be rotated by an actuator.

11. The substrate processing apparatus of claim 5, wherein the first roller comprises an idler roller configured to be rotated manually due to friction between the substrate and the first roller.

12. The substrate processing apparatus of claim 1,
wherein the signal processing unit generates revolutions data of the revolutions per unit time of the substrate over time, and
further comprises a data transmission unit configured to transmit, to a server, the revolutions data transmitted by the signal processing unit.

13. The substrate processing apparatus of claim 1, further comprising:
a cleaning brush configured to physically clean a main surface of the substrate,
wherein the cleaning brush is configured to rotate with respect to a direction in parallel with the main surface of the substrate.

14. A substrate processing apparatus configured to process a substrate having a notch, the substrate processing apparatus comprising:
a plurality of rollers arranged along a circumference of the substrate, and configured to rotate the substrate;
a first support pillar configured to support a first roller which is one of the plurality of rollers;
a first sensor bracket coupled to the first support pillar;
a first sensor mounted on the first sensor bracket, and configured to sense vibrations generated by impacts between the plurality of rollers and the substrate; and
a signal processing unit configured to detect a contact period between each of the plurality of rollers and the notch of the substrate based on a first sensing signal output by the first sensor.

15. The substrate processing apparatus of claim 14, further comprising:
a second support pillar configured to support a second roller which is one of the plurality of rollers;
a second sensor bracket coupled to the second support pillar; and
a second sensor mounted on the second sensor bracket, and configured to sense impacts between the plurality of rollers and the substrate,
wherein the signal processing unit is configured to detect a contact period between each of the plurality of rollers and the notch of the substrate, based on the first sensing signal and a second sensing signal output by the second sensor.

16. The substrate processing apparatus of claim 15, wherein each of the first sensor and the second sensor comprise an acceleration sensor.

17. A substrate processing apparatus configured to process a substrate having a notch, the substrate processing apparatus comprising:
a plurality of rollers arranged along a circumference of the substrate, and configured to rotate the substrate;
a first support pillar configured to support a first roller which is one of the plurality of rollers;
a first sensor bracket coupled to the first support pillar;
a first sensor mounted on the first sensor bracket, and configured to sense impacts between the plurality of rollers and the substrate;
a signal processing unit configured to detect revolutions per unit time of the substrate based on a first sensing signal output by the first sensor, and configured to generate revolutions data of the revolutions per unit time of the substrate over time;
a data transmission unit configured to transmit, to a server, the revolutions data transmitted by the signal processing unit;
a cleaning brush configured to physically clean a main surface of the substrate, and rotate with respect to a direction in parallel with the main surface of the substrate; and
a cleaning liquid spray nozzle configured to spray cleaning liquid to the substrate.

18. The substrate processing apparatus of claim 17,
wherein the first sensor comprises an acceleration sensor, and
wherein the first sensor is configured to detect an acceleration of the first roller in a first sensing direction, a second sensing direction, and a third sensing direction, which are perpendicular to each other.

19. The substrate processing apparatus of claim 17, wherein the first roller comprises a driving roller rotated by an actuator.

20. The substrate processing apparatus of claim 17, further comprising:
a second support pillar supporting a second roller which is one of the plurality of rollers;
a second sensor bracket coupled to the second support pillar; and
a second sensor mounted on the second sensor bracket, and configured to sense impacts between the plurality of rollers and the substrate,
wherein the first sensor and the second sensor comprise an acceleration sensor, and
wherein the signal processing unit is configured to detect the revolutions per unit time of the substrate based on the first sensing signal and a second sensing signal output by the second sensor.

21.-25. (canceled)
